(19) United States
(12) Patent Application Publication
(10) Pub. No.: US 2006/0205159 A1
(43) Pub. Date: Sep. 14, 2006

(54) Method of forming gate flash memory device

(75) Inventor: Eun Shil Park, Kyeongki-do (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Kyoungki-do (KR)

(21) Appl. No.: 11/295,386

(22) Filed: Dec. 5, 2005

(30) Foreign Application Priority Data
Mar. 10, 2005 (KR) 2005-20241

(51) Int. Cl. H01L 21/336

(52) U.S. Cl. 438/265; 438/266; 438/594

(57) ABSTRACT

A gate formation method of flash memory devices includes performing a nitrogen anneal process in a Rapid Thermal Processing (RTP) apparatus to crystallized a tungsten silicide film used as a control gate electrode, which results in reduced sheet resistance (Rs) of a control gate electrode. A Rapid Thermal Oxidization (RTO) process is performed for a short time period, thereby shortening the process time, preventing ONO smiling.

### BACKGROUND OF THE INVENTION

The present invention relates to a gate formation method of flash memory devices. More specifically, the present invention relates to a gate formation method of flash memory devices wherein the gate of a structure is formed, in which a floating gate, an Oxide/Nitride/Oxide (ONO) dielectric film, and a control gate are laminated.

A gate formation method of a conventional flash memory device will be described below with reference to FIGS. 1a and 1b.

FIGS. 1a and 1b are sectional views for illustrating a gate formation method of a flash memory device in the related art.

Referring to FIG. 1a, a lamination gate is formed in which a floating gate 13 and a control gate 18 are laminated on a semiconductor substrate 11. A tunnel oxide film 12 is formed between the floating gate 13 and the semiconductor substrate 11. An ONO structure in which a first oxide film 14a, a nitride film 14b, and a second oxide film 14c are laminated is widely used as the dielectric film 14. A tungsten silicide film 16 is formed on a polysilicon film 15 as a control gate.

In the above, during an etch process of forming the lamination gate in which the floating gate 13, the ONO dielectric film 14 and the control gate 18 are laminated, the gate sidewalls are exposed to plasma ambient and thus damaged. In addition, the edges of the tunnel oxide film 12 are also damaged, generating tunnel oxide film undercuts 17.

Referring to FIG. 1b, a thermal oxidization process for compensating for damage of the gate sidewalls and damage of the tunnel oxide film 12 is performed to form a thermal oxide film 100 on a surface of the exposed gate and the semiconductor substrate. Through the formation of the thermal oxide film 100, the damage of the gate sidewalls and the tunnel oxide film undercuts 17 are compensated for by the thermal oxide film 100 (indicated by reference numeral of 170). However, oxygen (O₂) within the first and second oxide films 14a, 14b, and silicon (Si) of the floating gate 13 and the polysilicon film 15 for a control gate react with each other to form a silicon oxide (SiO₂) film. Therefore, a smiling phenomenon is generated in the ONO dielectric film 14 (indicated by reference numeral of 100). The terms “smiling” refers to an increase of a thickness due to abnormal oxidization generated on the sidewalls of the ONO dielectric film 14.

The smiling phenomenon causes a voltage, which is applied to the control gate 18, to be irregularly transferred to the floating gate 13. As a result, the coupling ratio is lowered.

### BRIEF SUMMARY OF THE INVENTION

An advantage of the present invention is a gate formation method of a flash memory device, in which a gate is formed on a semiconductor substrate and nitrogen anneal and Rapid Thermal Oxidation (RTO) processes are then performed, whereby a reduction in sheet resistance (Rs) of a tungsten silicide film and excessive oxidization can be prevented and ONO smiling can be prevented or inhibited significantly.

A gate formation method of flash memory devices according to the present invention includes the steps of forming a tunnel oxide film, a polysilicon film for a floating gate, an ONO dielectric film, a polysilicon film for a control gate, a tungsten silicide film, and a hard mask on a semiconductor substrate, and performing an expose process and an etch process to form a gate line, after the formation step of the gate line, performing nitrogen anneal, and after the nitrogen anneal step, performing a RTO process to form an oxide film.

### BRIEF DESCRIPTION OF THE DRAWINGS

FIGS. 1a and 1b are sectional views for illustrating a gate formation method of a flash memory device in the related art; and

FIGS. 2a to 2d are sectional views for illustrating a gate formation method of flash memory devices according to embodiments of the present invention.

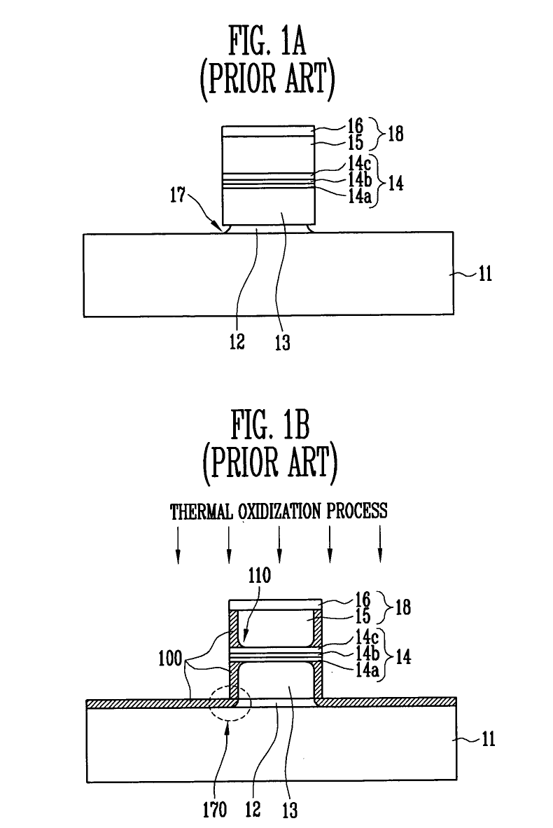

### DETAILED DESCRIPTION OF THE INVENTION

The present invention will now be described in connection with preferred embodiments with reference to the accompanying drawings.

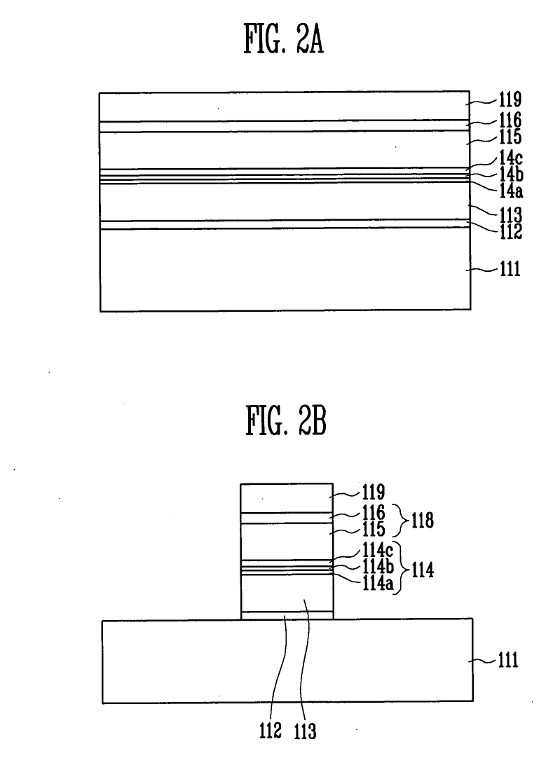

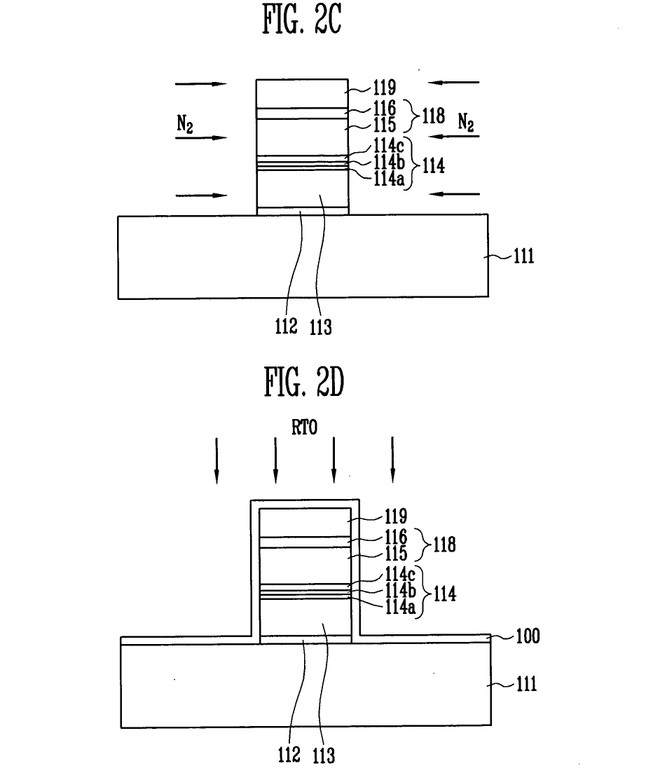

FIGS. 2a to 2d are sectional views for illustrating a gate formation method of flash memory devices according to one embodiment of the present invention.

Referring to FIG. 2a, a tunnel oxide film 112, a first polysilicon film 113 for a floating gate, a dielectric film 114 of an ONO structure, a second polysilicon film 115 for a control gate, a tungsten silicide film 116 as part of the control gate, and a gate hard mask 119 are sequentially deposited on a semiconductor substrate 111. The silicide film 116 may include other types of metal, e.g., titanium. The dielectric film 114 of the ONO structure has a structure in which a first oxide film 114a, a nitride film 114b, and a second oxide film 114c are laminated.

Referring to FIG. 2b, the tungsten silicide film 116, the second polysilicon film 115, the dielectric film 114, the first polysilicon film 113, and the tunnel oxide film 12 are selectively etched using the gate hard mask 119 as a barrier, thus forming a gate structure comprising the tunnel oxide film 112, the floating gate 113, the dielectric film 114, and the control gate 118.

Referring to FIG. 2c, in order to crystallize the tungsten silicide film 116, a nitrogen anneal (N₂ anneal) process is performed in a Rapid Thermal Processing (RTP) apparatus. The nitrogen anneal process is carried out at a temperature range of 800 to 1000° C. Furthermore, the flow rate of nitrogen is 10 to 20 sccm is used for a given period. In the present implementation, the annealing is performed for no more than 30 seconds. In another embodiment, the annealing is performed for no more than 25 seconds or 20 seconds. Through the nitrogen anneal process with the above condition, the tungsten silicide film 16 is crystallized, leading to reduced sheet resistance (Rs) of the control gate electrode. Furthermore, in a subsequent RTO process, excessive oxidization of the tungsten silicide film 16 can be prevented.

Referring to FIG. 2d, to alleviate damage incurred during the etch process of the gate line, a RTO process is performed to form an oxide film 100. The RTO process is performed in-situ after the nitrogen anneal process is performed in the RTP apparatus. The RTO process can be performed at a temperature range of 700 to 900° C. and can have the flow rate of oxygen of 5 to 10 sccm. The oxide film 100 by the RTO process can have a thickness of 20 to 40 Å. Through the RTO process, the damage associated with the gate etch process is alleviated. Since the RTO process is performed within a short period of time, the ONO smiling phenomenon can be prohibited.

As described above, in accordance with the present embodiment, since a nitrogen anneal process is performed in an RTP apparatus, a tungsten silicide film used as a control gate electrode can be crystallized, resulting in reduced sheet resistance (Rs) of a control gate electrode. Furthermore, since the RTO process is performed within a short period of time, the process time can be shortened, the ONO smiling can be prevented and the floating gate coupling ratio can be increased. Therefore, the program or erasing speed can be enhanced and device characteristics can be improved.

Although the foregoing description has been made with reference to the preferred embodiments, it is to be understood that changes and modifications to the above embodiments may be made by one of ordinary skill in the art without departing from the spirit and scope of the present invention, as defined in the appended claims.

What is claimed is:

1. A gate formation method of flash memory devices, the method comprising:
forming a gate structure over a substrate, the gate structure including a tunnel oxide film, a floating gate, a dielectric film, and a control gate;
annealing the gate structure in an environment including nitrogen; and
performing a Rapid Thermal Oxidation (RTO) process to form an oxide film enclosing the gate structure.

2. The method as claimed in claim 1, wherein the gate structure includes a tungsten silicide film, wherein the annealing is performed to crystallized the tungsten silicide.

3. The method as claimed in claim 1, wherein the anneal process is performed in a RTP apparatus.

4. The method as claimed in claim 1, wherein the anneal process is performed at a temperature range of 800 to 1000° C.

5. The method as claimed in claim 1, wherein the anneal process is performed within a chamber and involves providing nitrogen into the chamber at a flow rate of 10 to 20 sccm.

6. The method as claimed in claim 1, wherein the anneal process is performed for no more than 30 seconds.

7. The method as claimed in claim 1, wherein the RTO process is carried out in-situ in the same apparatus where the anneal process is performed.

8. The method as claimed in claim 1, wherein the RTO process is performed at a temperature range of 700 to 900° C.

9. The method as claimed in claim 1, wherein the RTO process is performed with a nitrogen flow rate of 5 to 10 sccm.

10. The method as claimed in claim 1, wherein the oxide film formed by the RTO process is 20 to 40 Å.

11. The method of claim 1, wherein the gate structure includes a hard mask formed over the control gate.

12. The method of claim 11, wherein the gate structure includes a silicide film provided below the hard mask.

13. The method of claim 12, wherein the control gate comprises a polysilicon film and the silicide film

14. The method of claim 13, wherein the silicide is tungsten silicide.

15. The method of claim 13, wherein the silicide includes titanium.
